(19) United States
(12) Patent Application Publication
(10) Pub. No.: US 2012/0243299 A1
(43) Pub. Date: Sep. 27, 2012

(54) POWER EFFICIENT DYNAMIC RANDOM ACCESS MEMORY DEVICES

(75) Inventor: Jeng-Jye Shau, Palo Alto, CA (US)

(73) Assignee: Jeng-Jye Shau, Palo Alto, CA (US)

(21) Appl. No.: 13/069,504

(22) Filed: Mar. 23, 2011

(51) Int. Cl. G11C 11/24; G11C 29/04

(52) U.S. Cl. 365/149; 365/200

(57) ABSTRACT

The present invention provides methods and structures for improving refresh power efficiency of dynamic random access memory devices. By measuring charge retention properties of reference cells that have substantially the same structures as normal DRAM memory cells, the refresh rate of DRAM devices can be adjusted with better reliability. The reliability is further improved by using ECC circuits and/or field programmable redundancy circuits.

### BACKGROUND OF THE INVENTION

The present invention relates to methods and structures developed to improve power efficiency of dynamic random access memory (DRAM) devices.

DRAM power consumption has three major components—input/output (I/O) power, core power, and refresh power. DRAM I/O power can be reduced by changing output driver design and/or termination circuits as disclosed in U.S. Pat. No. 7,180,338 and related patent publications. Significant reduction in DRAM core power can be achieved by reducing the bit line and/or word line loading of DRAM memory arrays using architectures disclose in U.S. Pat. No. 5,748,547 and related patent publications. DRAM refresh power is a complex function of temperature, size of memory cell storage capacitor, bit line loading, sensitivity of sensing circuits, operation voltage, manufacture processes, and other factors. By reducing bit line loading and sensitivity of sensing circuits, the architectures disclose in U.S. Pat. No. 5,748,547 and related patent publications can reduce refresh power by reducing DRAM refresh rate. Embedded DRAM equipped with the error correction code (ECC) circuits disclosed in U.S. Pat. No. 6,216,246 can reduce refresh rate significantly while supporting high performance operations. In order to save refresh power, Tillinghast et al. in U.S. Pat. No. 5,278,796, Koelling et al. in U.S. Pat. No. 6,281,760, Buckerbauer in U.S. Pat. No. 6,438,057, Cruz et al. in U.S. Pat. No. 7,295,484, and Chang in U.S. Pat. No. 7,035,157 disclosed methods that adjust DRAM refresh rate according to temperature measurements. However, temperature is not the only factor that determines DRAM refresh rate. Multiple leakage mechanisms with different temperature dependence may co-exist as the limiting factors for DRAM refresh rate. Therefore, relying on temperature measurement along is often not adequate. Tsern in U.S. Pat. No. 7,734,866 disclosed a method that adjust DRAM refresh rate for memory cells at different addresses. This method requires complex control that is typically not compatible with existing DRAM controllers. Ito et al. in U.S. Pat. No. 7,216,198 and in US. Patent Application Number 2005/0286331 disclosed methods that use corrected data count detected by on-chip ECC circuit during a data retention mode to adjust refresh time in order to reduce DRAM refresh power. This method is equivalent to test the whole DRAM array continuously so that its test coverage is typically adequate. However, if there are failure bits that are not recoverable by ECC, this method would fail. In addition, Ito's method requires significant cost overhead in additional memory array used to store ECC data; it also requires power overhead for reading the whole memory and executing ECC calculations. Most importantly, Ito's method would cause access conflicts with DRAM normal read/write operations so that it is useful only when the DRAM is in a special mode that stops all read/write operations. Ito's method is therefore not useful without going into special data retention mode. Using Ito's data retention mode, additional power and performance overhead would be required for going into and leaving the special mode. It is therefore highly desirable to provide reliable and cost efficient DRAM refresh power saving methods that is applicable during DRAM normal operations.

### SUMMARY OF THE PREFERRED EMBODIMENTS

The primary objective of the preferred embodiments is, therefore, to improve DRAM power efficiency. One primary objective of the preferred embodiments is to reduce DRAM refresh power. One objective of the preferred embodiments is to improve DRAM refresh power efficiency without getting into special power saving mode. Another objective of the preferred embodiments is to adjust DRAM refresh rate based on parameters more reliable then temperature measurements. One objective of the preferred embodiments is to reduce cost overhead of DRAM power saving methods. Another objective of the preferred embodiments is to reduce power overhead of DRAM power saving methods. These and other objectives are achieved by measuring refresh rate related parameters of DRAM memory cells as indicator to adjust DRAM refresh rates. These and other objectives also can be assisted by ECC circuits and/or field programmable redundancy circuits.

While the novel features of the invention are set forth with particularly in the appended claims, the invention, both as to organization and content, will be better understood and appreciated, along with other objects and features thereof, from the following detailed description taken in conjunction with the drawings.

### BRIEF DESCRIPTION OF THE DRAWINGS

FIGS. 1(a, b) are exemplary symbolic block diagrams showing an integrated circuit semiconductor device comprising DRAM memory cells and reference cells;

FIGS. 2(a-d) are exemplary symbolic diagrams for testing circuits that measure charge retention properties of reference cells;

FIG. 3 is an exemplary float chart for adjusting DRAM refresh rate according to reference cell measurements; and

FIGS. 4(a-d) block diagrams for integrated circuits with reference cell testing circuits, field programmable redundancy circuits, and ECC protection circuits.

### DETAILED DESCRIPTION OF THE PREFERRED EMBODIMENTS

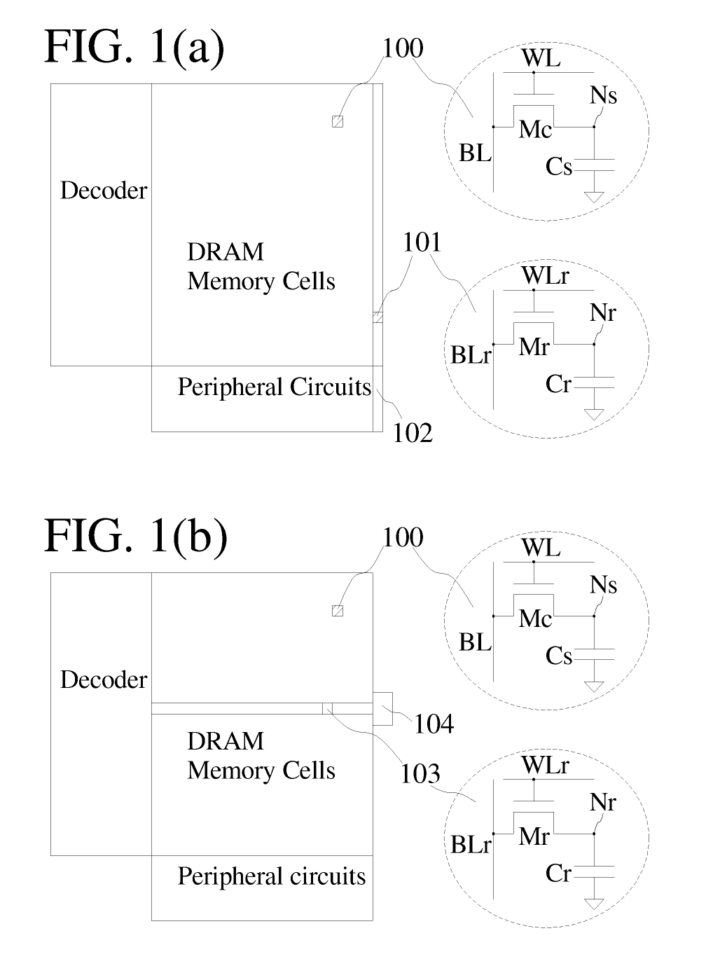

FIG. 1(a) shows a simplified symbolic view for an integrated circuit (IC) semiconductor device that comprises large number of dynamic random access memory (DRAM) memory cells (100), reference cell (101), and testing circuits (102) used to measure the charge retention properties of reference cell(s). Preferred embodiment of the present invention is typically applied on IC devices with millions or more DRAM memory cells so that reduction in DRAM refresh rate represent significant power savings. A typical DRAM memory cell (100) comprises one transistor (Mc) and one storage capacitor (Cs); the gate of the transistor (Mc) is connected to a word line (WL), the drain of the transistor is connected to a bit line (BL), and the source of the transistor is connected to the storage capacitor (Cs). The structures of a reference cell (101) are typically manufactured to be very similar to a typical DRAM memory cell. The exemplary reference cell (101) shown in FIG. 1(a) is placed near the DRAM memory cells, and it has the same structures as a typical DRAM memory cell (100). This reference cell (101) comprises one transistor (Mr) and one storage capacitor (Cr); the gate of the transistor (Mr) is connected to a word line (WLr), the drain of the transistor is connected to a bit line (BLr), and the source of the transistor is connected to the capacitor (Cr), as illustrated in FIG. 1(a). Other embodiments of reference cells may not have all the features of normal DRAM memory cells, but reference cells typically have a capacitor that is substantially similar to the storage capacitor of normal DRAM memory cells. The IC device also comprises testing circuits (102) for measuring charge retention properties of reference cell(s) and outputting electrical signal(s) used for adjusting the refresh rates of said DRAM memory cells. The reference cell(s) (101) are typically placed near the DRAM memory cells (100) in order to sample the environment of normal DRAM memory cells. There are many ways to place the reference cells; the example shown in FIG. 1(a) has one vertical line of reference cells (101) while the example shown in FIG. 1(b) has one horizontal line of reference cells (103). There are also many ways to place the reference cell testing circuits (102, 104), as illustrated by the examples in FIGS. 1(a, b).

The data stored in a DRAM memory cell (100) is represented by the electrical charges stored in its storage capacitor (Cs). Electrical charges in the DRAM memory cell may leak away due to many possible mechanisms. For example, electrical charges may leak through the select transistor (Mc) due to transistor sub-threshold leakage current; electrical charges may leak away through defects in the insulator layer of the storage capacitor, leak away due to junction leakage current, or disturbed by activities of nearby memory cells. It is therefore necessary to refresh DRAM memory cells before the lost of electrical charges in the storage capacitor is enough to cause false data reading. Measuring the charge retention properties of DRAM memory cells can provide effective indicator in controlling DRAM refresh rate. Measuring DRAM memory cells directly would cause conflicts with normal memory operations. Measuring reference cells with similar properties as normal DRAM memory cells provides effective indicator without disturbing normal memory operations.

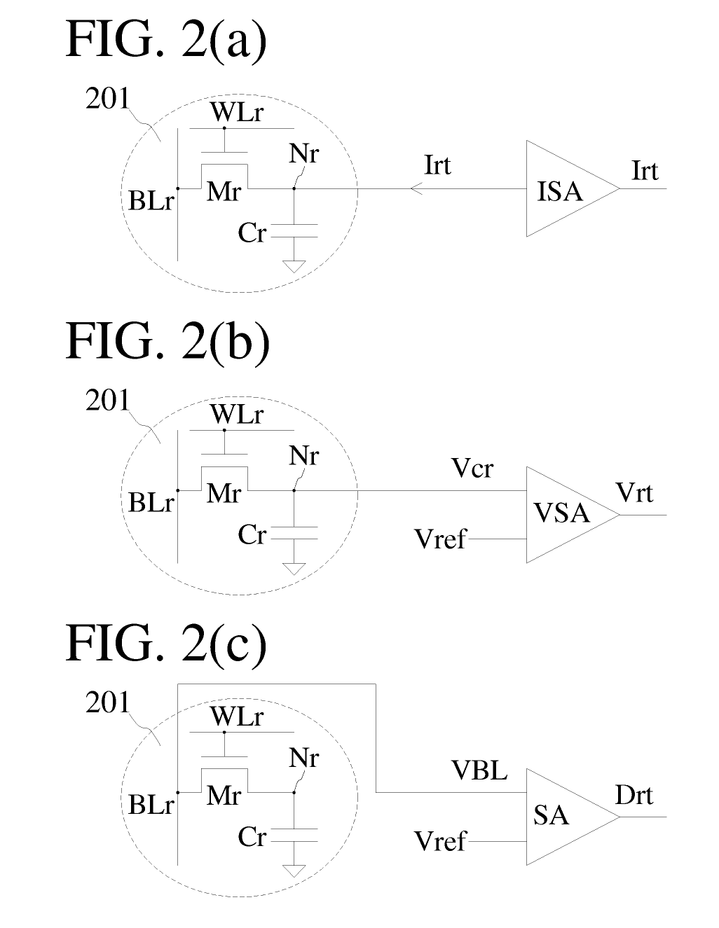

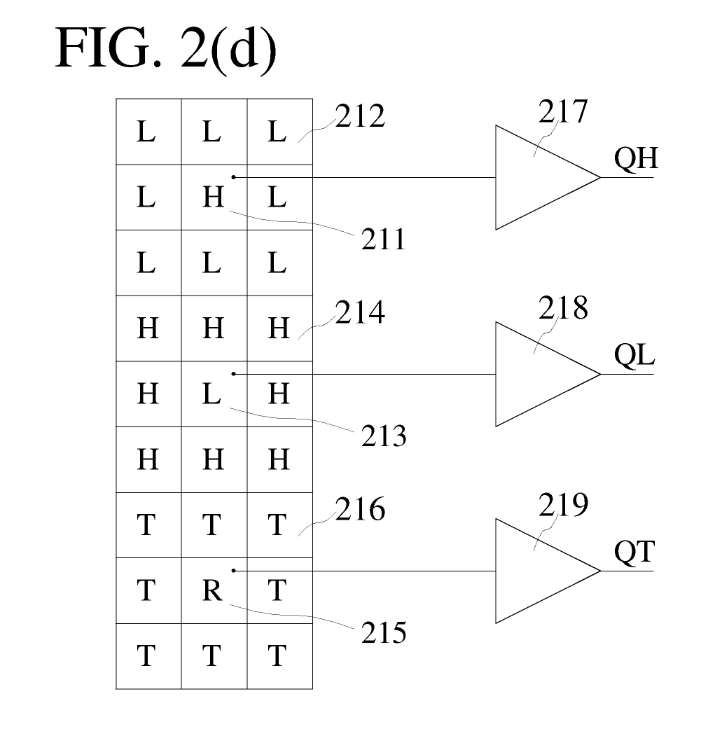

There are many ways to measure charge retention properties of reference cells. FIGS. 2(a-d) are simplified symbolic diagrams for exemplary reference cell testing circuits. FIG. 2(a) shows an example when a current sensor (ISA) is used to measure the leakage current (Irt) of the storage node (Nr) in a reference cell (201). The output (Irt) of the current sensor (ISA) can be used as an indicator for adjusting DRAM refresh rates. FIG. 2(b) shows an example when a voltage sensor (VSA) is used to measure the voltage (Vcr) of the storage node (Nr) in a reference cell (201). In this example, the voltage Vcr is compared with a reference voltage (Vref), and output (Vrt) of the voltage sensor (VSA) can be used as an indicator for adjusting DRAM refresh rates. FIG. 2(c) shows an example when a data sensor (SA) is used to detect the data stored in the reference cell (201). The word line (WLr) of the reference cell (201) is turned on in a pre-determined rate; when the select transistor (Mr) is turned on, the electrical charge in the reference cell capacitor (Cr) cause voltage changes (VBL) on the bit line (BLr); the sensor (SA) determines if the reference cell still stores the right data, and provides an output (Drt) that can be used as an indicator for adjusting DRAM refresh rates.

While the preferred embodiments have been illustrated and described herein, other modifications and changes will be evident to those skilled in the art. It is to be understood that there are many other possible modifications and implementations so that the scope of the invention is not limited by the specific embodiments discussed herein. For example, it is possible to combine reference cell measurements with prior art indicators such as temperature measurement to adjust refresh rates. The testing circuits illustrated in FIGS. 2(a-c) measure charge retention properties of one reference cells, while other testing circuits may measure multiple reference cells. It is also desirable to measure multiple charge retention properties of various reference cells under different environments in order to provide sufficient indicators. Sometimes, it is desirable to measure charge retention properties of reference cells in different environment. FIG. 2(d) shows simplified symbolic views of reference cell test circuits that comprise three sensors; a sensor (217) measures the charge retention properties of a reference cell (211) charged with high voltage (H) when the reference cell (211) is surrounded by cells (212) charged with low voltage (L); another sensor (218) measures the charge retention properties of a reference cell (213) charged with low voltage (L) when the reference cell (213) is surrounded by cells (214) charged with high voltage (H); and, another sensor (219) measures the charge retention properties of a reference cell (215) when the reference cell (215) is surrounded by cells (216) that are toggled (T) periodically with different voltages. The outputs (QH, QL, QT) of these sensors (217-219) may provide better indicators because they measure the charge retention properties of reference cells (211, 213, 215) in different environments.

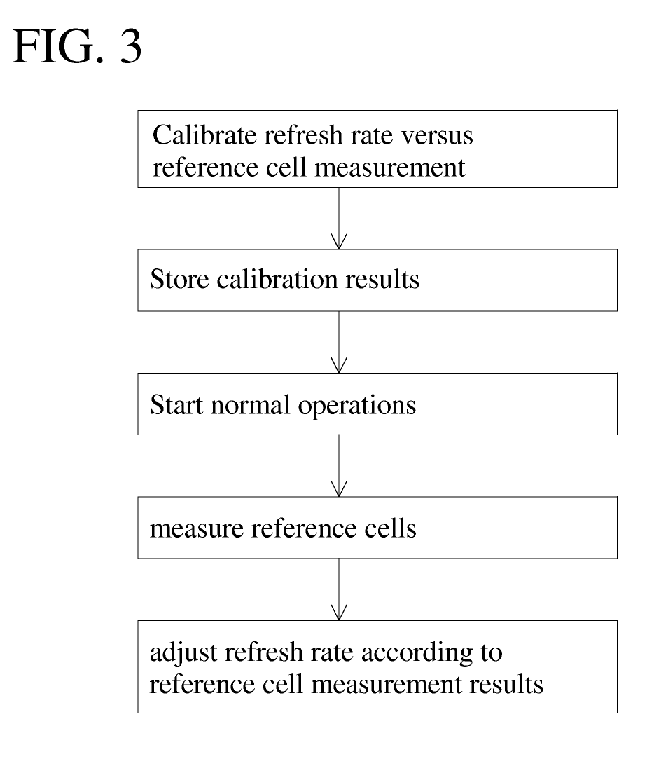

FIG. 3 shows a simplified flow chart for exemplary procedures using reference cell measurements to assist control of DRAM refresh rates. The integrated circuit semiconductor device with millions or more DRAM memory cells is tested under different conditions to calibrate the correlation between the outputs of reference cell testing circuits and the required refresh rates. Preferably, the calibration results are stored in nonvolatile memory devices such as a FLASH memory device or a hard disc. When an application starts normal operations on the IC device, the reference cell testing circuits continue to measure reference cells, and the refresh rate of DRAM memory cells are adjust according to the outputs of reference cell measurements in order to achieve optimum refresh power efficiency. Typically, reduction in refresh power by more than one order of magnitude can be achieved by such methods. Measurements on reference cells provide better correlation than prior art methods such as temperature measurements. Measurements in reference cells also do not disturb normal DRAM read/write operations.

While the preferred embodiments have been illustrated and described herein, other modifications and changes will be evident to those skilled in the art. It is to be understood that there are many other possible modifications and implementations so that the scope of the invention is not limited by the specific embodiments discussed herein. Reference cell measurements provide excellent indicators of the charge retention properties of typical DRAM memory cells. However, for IC devices with millions or billions of memory cells, the refresh rates of the IC devices maybe determined by a few defective memory cells. Since the charge retention properties of defective memory cells maybe completely different from the properties of typical memory cells, reference cell measurements are therefore less effective in predicting the behaviors of defective memory cells. It is therefore desirable to apply features that remove the effects of defective memory cells in combination with reference cell measurements.

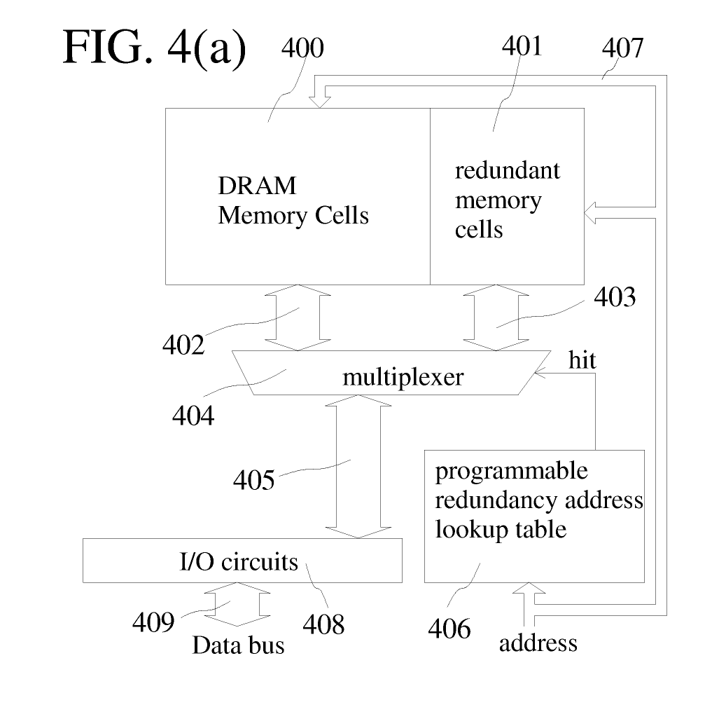

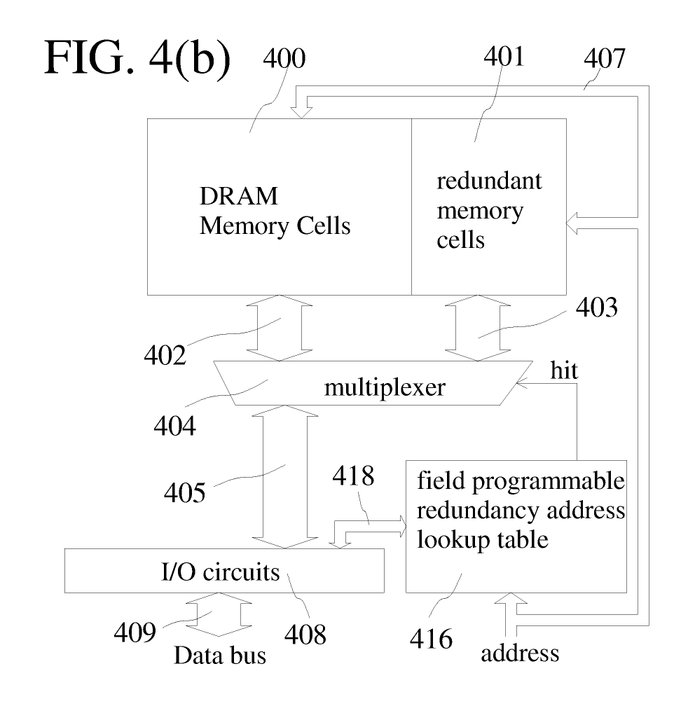

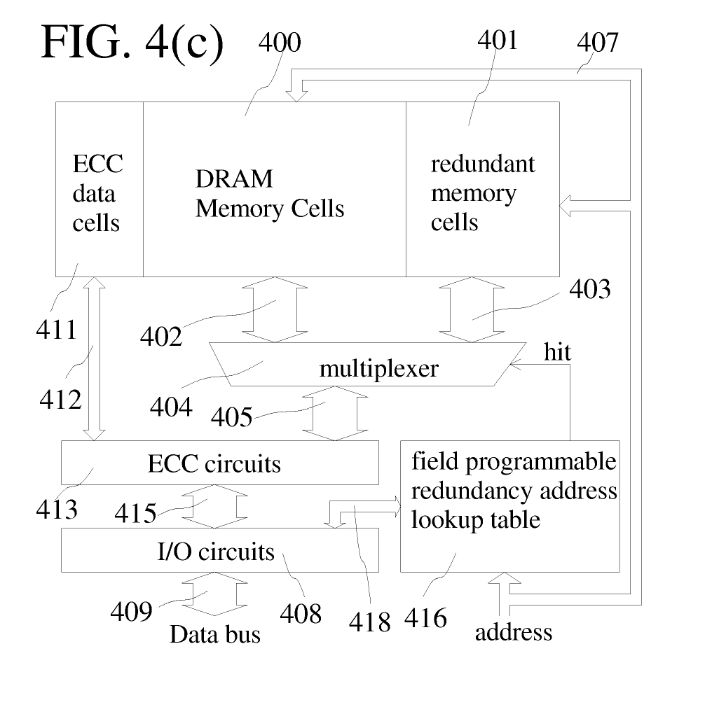

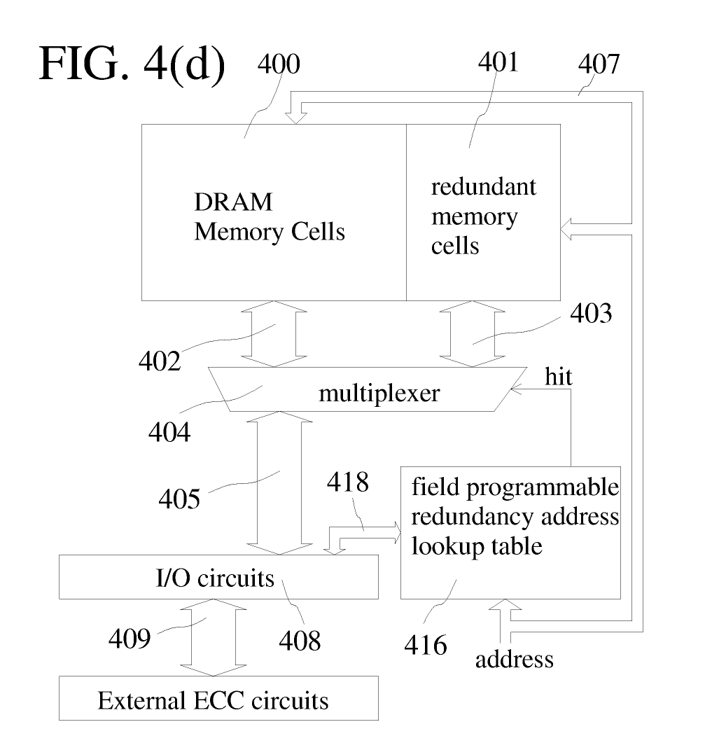

One method to remove the effects of defective memory cells is to use redundancy circuits to replace the functions of defective memory cells. FIG. 4(a) is a exemplary symbolic block diagram for an IC quipped with redundancy circuits. Besides normal DRAM memory cells (400), this IC has redundant memory cells (401) that can be used to replace defective memory cells. The redundant memory cells can be DRAM or other types of memory cells. When defective cells are found in the normal DRAM memory cells (400), a sub-set of the address (such as the column address or the row address) of the defective cells are stored into a programmable redundancy address lookup table (406). During a DRAM operation, the target address (407) is sent to the normal DRAM memory array (400), redundant memory array (401), and the redundancy address lookup table (406). The lookup table (406) compares the target address with known addresses of defective memory cells, and outputs a hit signal that controls a multiplexer (404). If the address is different from any address of defective memory cells, the output of the lookup table selects the data path (402) of the normal memory array (400) as the data path of the memory (405), and the memory operation is executed normally. If the address matches with one of the addresses of defective memory cells, the multiplexer selects the data path (403) of the redundant memory array to replace the data path (402) of the normal DRAM array so that the data path (405) to the defective cells would be replaced by the data path to redundant memory cells. In this way, the external data (409) input/output to the IC can bypass known defective memory cells.

The redundancy circuits illustrated in FIG. 4(b) work well if the addresses of all the defective memory cells are found and stored in the lookup table (416). Typical method to program the lookup table is to use fuses burnt by LASER beams. Such method is not applicable after the IC is packaged or after the IC is stacked with other IC. Sometimes, memory cells with charge retention problems can be found after the IC has been packaged or stacked. Laser beams can not program redundancy circuits after packaging. It is therefore desirable to have field programmable redundancy circuits that are programmable after the IC has been package or after the IC has been stacked with other IC. FIG. 4(b) is a symbolic block diagram for an IC quipped with exemplary field programmable redundancy circuits. Most of the features in FIG. 4(b) are similar to those in FIG. 4(a) except that the redundancy lookup table (416) in this example has a data path (418) connected to the I/O circuits (408). This data path (418) allows external circuits to read or write the contents of the field programmable redundancy address lookup table (416). Therefore, the contents of the lookup table can be programmed by external circuits after the IC has been packaged or stacked. It is desirable to store the addresses of defective memory cells in nonvolatile memory devices. The nonvolatile memory device and be embedded nonvolatile device in the same IC or nonvolatile memory devices external to the IC, such as the EPROM devices typically found in DRAM memory modules or the hard discs in computers. This and other field programmable DRAM redundancy circuits provide additional flexibility to replace defective memory cells.

Besides redundancy circuits, another effective feature to remove the effects of defective memory cells is error correction code (ECC) circuits. FIG. 4(c) is a symbolic block diagram for an IC quipped with internal ECC circuits as well as field programmable redundancy circuits. Besides normal DRAM memory cells (400), this IC provides addition ECC data cells (411) to store ECC data. For each set of memory data, ECC circuits (413) calculate ECC data (412), and store the ECC data into the ECC data cells (411). During memory read operations, memory data outputs (405) as well as the ECC data (412) are sent to the ECC circuits (413). The ECC circuits are able to correct error and provide corrected data (415) to the I/O circuits (408). Please refer to U.S. Pat. No. 6,216,246 for further details of ECC operations. Using ECC, the properties of DRAM will be dominated by typical memory cells instead of defective memory cells, making reference cell measurements more effective in optimizing refresh power efficiency.

While the preferred embodiments have been illustrated and described herein, other modifications and changes will be evident to those skilled in the art. It is to be understood that there are many other possible modifications and implementations so that the scope of the invention is not limited by the specific embodiments discussed herein. For example, instead of using embedded ECC circuits illustrated in FIG. 4(c), ECC calculations external to the IC device also can be used to achieve similar purpose, as illustrated in FIG. 4(d).

Preferred embodiments of the present invention improves DRAM refresh power for integrated circuit semiconductor devices that comprise millions or more DRAM memory cells. Testing circuits of one preferred embodiment measure the leakage current(s) of the reference cell(s) and provide output signal(s) as indicator(s) used for adjusting DRAM refresh rates. Testing circuits of another preferred embodiment measure the voltage(s) on the capacitor(s) in the reference cell(s) and provide output signal(s) as indicator(s) used for adjusting refresh rates. Testing circuits of another preferred embodiment measure the data stored in the reference cell(s) and provide output signal(s) as indicator(s) used for adjusting refresh rates. To avoid influences of defective memory cells, one preferred embodiment further comprises programmable redundancy circuits for replacing the functions of selected memory cell(s) in the DRAM memory cells, wherein said programmable redundancy circuits are programmable after the integrated circuit semiconductor device has been packaged or after the integrated circuit semiconductor device has been stacked with other integrated circuit semiconductor device(s). The refresh rates of the DRAM memory cells are programmable after the integrated circuit semiconductor device has been packaged. For another preferred embodiment, the integrated circuit semiconductor device further comprises ECC circuits for correcting the data stored in the DRAM memory cells.

While specific embodiments of the invention have been illustrated and described herein, it is realized that other modifications and changes will occur to those skilled in the art. It is therefore to be understood that the appended claims are intended to cover all modifications and changes as fall within the true spirit and scope of the invention.

What is claimed is:

1. An integrated circuit semiconductor device comprising:
(a) millions or more DRAM memory cells, wherein each DRAM memory cell comprise one transistor and one storage capacitor;
(b) one or more reference cell(s) wherein each reference cell comprises at least one capacitor that has substantially the same structures as the storage capacitors of said DRAM memory cells;
(c) testing circuits for measuring charge retention properties of said reference cell(s) and outputting electrical signal(s) as indicator(s) used for adjusting the refresh rates of said DRAM memory cells.

2. The integrated circuit semiconductor device in claim 1 comprises testing circuits that measure the leakage current(s) of the reference cell(s) and provide output signal(s) as indicator(s) used for adjusting the refresh rates for DRAM memory cells in said integrated circuit semiconductor device.

3. The integrated circuit semiconductor device in claim 1 comprises testing circuits that measure the voltage(s) on the capacitor(s) in the reference cell(s) and provide output signal(s) as indicator(s) used for adjusting the refresh rates for DRAM memory cells in said integrated circuit semiconductor device.

4. The integrated circuit semiconductor device in claim 1 comprises testing circuits that measure the data stored in the reference cell(s) and provide output signal(s) as indicator(s) used for adjusting the refresh rates for DRAM memory cells in said integrated circuit semiconductor device.

5. The integrated circuit semiconductor device in claim 1 further comprises programmable redundancy circuits for replacing the functions of selected memory cell(s) in the DRAM memory cells, wherein said programmable redundancy circuits are programmable after the integrated circuit semiconductor device has been packaged or after the integrated circuit semiconductor device has been stacked with other integrated circuit semiconductor device(s).

6. The refresh rates of the DRAM memory cells in the integrated circuit semiconductor device in claim 1 are programmable after the integrated circuit semiconductor device has been packaged.

7. The integrated circuit semiconductor device in claim 1 further comprises error correction code (ECC) circuits for correcting the data stored in the DRAM memory cells in said integrated circuit semiconductor device.

8. A method for adjusting the DRAM refresh rate of an integrated circuit semiconductor device that comprises millions or more DRAM memory cells, said method comprises the steps of:
(a) providing one or more reference cell(s) wherein each reference cell comprises at least one capacitor that has substantially the same structures as the storage capacitors of the DRAM memory cells in the integrated circuit semiconductor device;
(b) providing testing circuits to measure charge retention properties of said reference cell(s);
(c) adjusting DRAM refresh rates using the output(s) of said testing circuits.

9. The method in claim 8 further comprises a step of providing testing circuits that measure the leakage current(s) of the reference cell(s).

10. The method in claim 8 further comprises a step of providing testing circuits that measure the voltage(s) on the capacitor(s) in the reference cell(s).

11. The method in claim 8 further comprises a step of providing testing circuits that measure the data stored in the reference cell(s).

12. The method in claim 8 further comprises a step of providing programmable redundancy circuits for replacing the functions of selected memory cell(s) in the DRAM memory cells, wherein said programmable redundancy circuits are programmable after the integrated circuit semiconductor device has been packaged or after the integrated circuit semiconductor device has been stacked with other integrated circuit semiconductor device(s).

13. The method in claim 8 further comprises a step of making the refresh rates of the DRAM memory cells in the integrated circuit semiconductor device programmable after the integrated circuit semiconductor device has been packaged.

14. The method in claim 8 further comprises a step of providing ECC circuits for correcting the data stored in the DRAM memory cells in the integrated circuit semiconductor device.

15. An integrated circuit semiconductor device comprising:
(a) millions or more DRAM memory cells;
(b) programmable redundancy circuits for replacing the functions of selected memory cells in said DRAM memory cells, wherein said programmable redundancy circuits are programmable after the integrated circuit semiconductor device has been packaged or after the integrated circuit semiconductor device has been stacked with other integrated circuit semiconductor device(s).

16. The integrated circuit semiconductor device in claim 15 further comprises embedded nonvolatile memory devices to store the addresses of the selected DRAM memory cells that are replaced by the programmable redundancy circuits in the integrated circuit semiconductor device.

17. The integrated circuit semiconductor device in claim 15 further comprises circuits for outputting the addresses of the selected DRAM memory cells that are replaced by the programmable redundancy circuits in the integrated circuit semiconductor device.
